(19) United States
(12) Patent Application Publication
(10) Pub. No.: US 2008/0191772 A1
(43) Pub. Date: Aug. 14, 2008

(54) Clock Correction Circuit and Method

(76) Inventors: Andrew J. Pickering, Rugby (GB); Peter Hunt, Bugbrooke (GB); Robert Killips, Daventry (GB); Simon Forey, Earls Barton (GB)

Correspondence Address: TEXAS INSTRUMENTS INCORPORATED, P O BOX 655474, M/S 3999, DALLAS, TX, 75265, US

(21) Appl. No.: 12/028,523

(22) Filed: Feb. 8, 2008

Related U.S. Application Data
(60) Provisional application No. 61/017,057, filed on Dec. 27, 2007.

(30) Foreign Application Priority Data
Feb. 9, 2007 (GB) 0702628.9

(51) Int. Cl. H03K 3/00

(52) U.S. Cl. 327/243; 327/238

(57) ABSTRACT

The present invention relates to the reduction in errors in the phase of quadrature clock signals and provides a correction circuit for signals which are required to have as close to that precise phase relationship as possible. The arrangement is based upon a circuit which aims to bring signals which should be 180 degrees apart closer to a 50% duty cycle.

This application claims priority under 35 U.S.C. 119(a) to GB Provisional Application No. 0702628.9 filed Feb. 9, 2007.

This application claims priority under 35 U.S.C. 119(e)(1) to U.S. Provisional Application No. 61/017,057 (TI-63555P) filed Dec. 27, 2007.

### BACKGROUND OF THE INVENTION

1. Field of the Invention

The present invention relates to the reduction in errors in the phase of quadrature clock signals.

It is known to generate clock signals in quadrature; that is having relative phases of 0 degrees, 90 degrees, 180 degrees and 270 degrees. Typically, a phase locked loop (PLL) is used to generate such clock signals. Often, the output of the phase locked loop circuit is a small-swing signal. It is often necessary to convert that signal into a large swing signal; for example of the form output by CMOS logic gates.

2. Description of Related Art

FIG. 6 is a block diagram of a known clock generator circuit, indicated generally by the reference numeral 600. The circuit 600 comprises a PLL 602, a phase adjust circuit 604 and a small-signal to large-signal converter 606. The PLL 602 outputs four small-swing clock signals in quadrature; that is, having relative phases of 0 degrees, 90 degrees, 180 degrees and 270 degrees. The outputs of the PLL form the inputs of phase adjust circuit 604. The phase adjust circuit 604 adjusts the absolute phases of the clock signals under the control of a control input CTRL and outputs four adjusted clock signals, which are still in quadrature. The outputs of the phase adjust circuit are small-swing clock signals that form the inputs to converter 606, which converts the small-swing clock signals into large swing clock signals, which clock signals are still in quadrature.

The implementation of PLL 602 and phase adjust circuit 604 is within the competence of those skilled in the art and no further description of those circuit elements will be provided here.

A problem with the arrangement of FIG. 6 is that errors can occur in the relative phases of the clock signal so that they are not in perfect quadrature. There is no means provided in the arrangement of FIG. 6 for correcting quadrature errors: accordingly, errors introduced at any stage simply propagate through the circuit. Such quadrature errors can present problems to circuits that rely on incoming clock signals being presented in quadrature.

### SUMMARY OF THE INVENTION

The present invention provides a clock correction circuit comprising:
a differential amplifier comprising first and second inputs and first and second outputs, wherein, in use, said first and second inputs receive first and second small signal clock signals respectively;

a first push-pull output stage comprising an input and an output, wherein said input is coupled to the first output of said differential output and said output provides a first clock output signal;

a second push-pull output stage comprising an input and an output, wherein said input is coupled to the second output of said differential output and said output provides a second clock output signal;

a first feedback loop circuit comprising an input and an output, wherein the input is coupled to the output of said first push-pull output stage and wherein said first feedback loop circuit is adapted to provide a first control signal at said output that is indicative of the difference between the mean level of said first clock output signal and a desired mean level of said first clock output signal, wherein the output of said first feedback loop is coupled to a control input of said first push-pull output stage; and

a second feedback loop circuit comprising an input and an output, wherein the input is coupled to the output of said second push-pull output stage and wherein said second feedback loop circuit is adapted to provide a second control signal at said output that is indicative of the difference between the mean level of said second clock output signal and a desired mean level of said second clock output signal, wherein the output of said second feedback loop is coupled to a control input of said second push-pull output stage,

wherein the current drive of an input stage of said first push-pull output stage is dependent on the output of said first feedback loop circuit and the current drive of an input stage of said second push-pull output stage is dependent on the output of said second feedback loop circuit, such that, in use, the mean level of the signals at said first and second outputs of said clock correction circuit are adjusted towards the said desired mean levels.

The said first and second output clock signals may be complementary clock signals.

The first feedback loop circuit may comprises a first low pass filter and a first comparator and said second feedback loop circuit may comprise a second low pass filter and a second comparator. Further, the first low pass filter may have an input coupled to the output of said first push-pull output stage and an output coupled to a first input of said first comparator; the first comparator may have an output providing said first control signal; the second low pass filter may have an input coupled to the output of said second push-pull output stage and an output coupled to a first input of said second comparator; and said second comparator has an output providing said second control signal.

The said first comparator may have a second input connected to a voltage equivalent to said desired mean level of said first output clock signal and said second comparator may have a second input connected to a voltage equivalent to said desired mean level of said second output clock signal.

In one form of the invention, the desired mean levels of said signals at said first and second outputs of said clock correction circuit are 50% of the supply voltage.

In one form of the invention, the differential amplifier further comprises a variable current source controlled in dependence on a control input.

The present invention also provides a clock control circuit comprising:

a first clock correction circuit having first and second inputs for receiving first and second small signal clock signals and first and second outputs for providing first and second large signal clock signals, said first clock correction circuit comprising a first differential amplifier having a variable current source controlled in dependence on a control input;

a second clock correction circuit having first and second inputs for receiving third and fourth small signal clock signals and first and second outputs for providing third and fourth large signal clock signals, said second clock correction circuit comprising a second differential amplifier having a variable current source controlled in dependence on a control input;

a clock multiplier having first and second inputs coupled to said first and second outputs of said first clock correction circuit and third and fourth inputs coupled to said first and second outputs of said second clock correction circuit, wherein, when the signals at the first and second inputs of said clock multiplier are complementary and the signals at the third and fourth inputs of said clock multiplier are complementary, the output of the clock multiplier is given by both the exclusive OR of the first and third inputs and the exclusive OR of the second and fourth input; and

a control circuit comprising first and second inputs coupled to the first and second outputs of said clock multiplier respectively and first and second outputs coupled to the control inputs of said first and second clock correction circuit respectively, wherein:
when the signal at the first output of said clock multiplier is high for a longer period of time that the signal at said second output of said clock multiplier, the first output of said control circuit has a higher voltage than the second output of said control circuit; and

when the signal at the second output of said clock multiplier is high for a longer period of time that the signal at said first output of said clock multiplier, the second output of said control circuit has a higher voltage than the first output of said control circuit,
whereby the current drive of the first differential amplifier is dependent on the first output of said control circuit and the current drive of the second differential amplifier is dependent on the second output of said control circuit, such that, is use, said first, second, third and fourth large signal clock signals are adjusted towards quadrature.

When the four clock signals are in quadrature, the clock multiplier operates such that whenever one of the clock signals changes state, the output of the clock multiplier changes state.

In one form of the invention, the clock multiplier is arranged such that a first output of said clock multiplier is pulled high if said first and fourth inputs of said clock multiplier are both low or if said second and third inputs of said clock multiplier are both low and the first output of said clock multiplier is pulled low if said first and third inputs of said clock multiplier are both high or if said second and fourth inputs of said clock multiplier are both high.

### BRIEF DESCRIPTION OF THE DRAWINGS

Examples of the invention will now be described with reference to the accompanying drawings, of which:

FIG. 1 is a block diagram of a receiver circuit, in which the invention may be used;

FIG. 2 shows the feed forward equaliser and the decision feedback equaliser of the receiver circuit of FIG. 1;

FIG. 3 is a graph showing the post equalised signal amplitude for exemplary bit patterns;

FIG. 4 is a diagram of a transmitter, in which the invention may be used;

FIG. 5a shows the response of the receiver to a PRBS transmitted eye-pattern;

FIG. 5b shows the interleaved output of the ADCs of the receiver;

FIG. 6 shows a known clock generation circuit;

FIG. 7 is a block diagram of a clock control circuit in accordance with an embodiment of the present invention;

FIG. 8 is a schematic circuit diagram of a CML-CMOS converter in accordance with an aspect of the present invention; and

FIG. 9 shows a control circuit used in an embodiment of the present invention;

FIG. 10 shows a clock multiplier circuit used in an embodiment of the present invention;

FIG. 11 is a timing diagram demonstrating the functionality of the clock multiplier circuit of FIG. 10; and

FIG. 12 shows a part of the CML-CMOS converter of FIG. 8 in accordance with an aspect of the present invention.

### DETAILED DESCRIPTION OF THE PREFERRED EMBODIMENT

A key challenge facing designers of high-bandwidth systems such as data-routers and super-computers is the requirement to transfer large amounts of data between ICs—either on the same circuit board or between boards. This data transmission application is called Serialisation-Deserialisation or “SerDes” for short. The present invention is useful in SerDes circuit and indeed was developed for that application. Nonetheless the invention may be used in other applications.

Analysis of typical backplane channel attenuation (which is around −24 dB) and package losses (−1 to −2 dB) in the presence of crosstalk predict that an un-equalized transceiver provides inadequate performance and that decision feedback equalization (DFE) is needed to achieve error rates of less than 10⁻¹⁷.

Traditional decision-feedback equalization (DFE) methods for SerDes receivers rely on either modifying, in analogue, the input signal based on the data history [“A 6.25 Gb/s Binary Adaptive DFE with First Post-Cursor tap Cancellation for Serial backplane Communications” R Payne et al ISSCC 2005; “A 6.4 Gb/s CMOS SerDes Core with feed-forward and Decision Feedback Equalization” M. Sorna et al ISSCC 2005; “A 4.8-6.4 Gb/s serial Link for Backplane Applications Using Decision Feedback Equalization” Balan et al IEEE JSSC November 2005.] or on having an adaptive analogue slicing level [“Techniques for High-Speed implementation of Non-linear cancellation” S. Kasturia IEEE Journal on selected areas in Communications. June 1991.] (i.e. the signal level at which the circuit decides whether the signal represents a 1 or a 0).

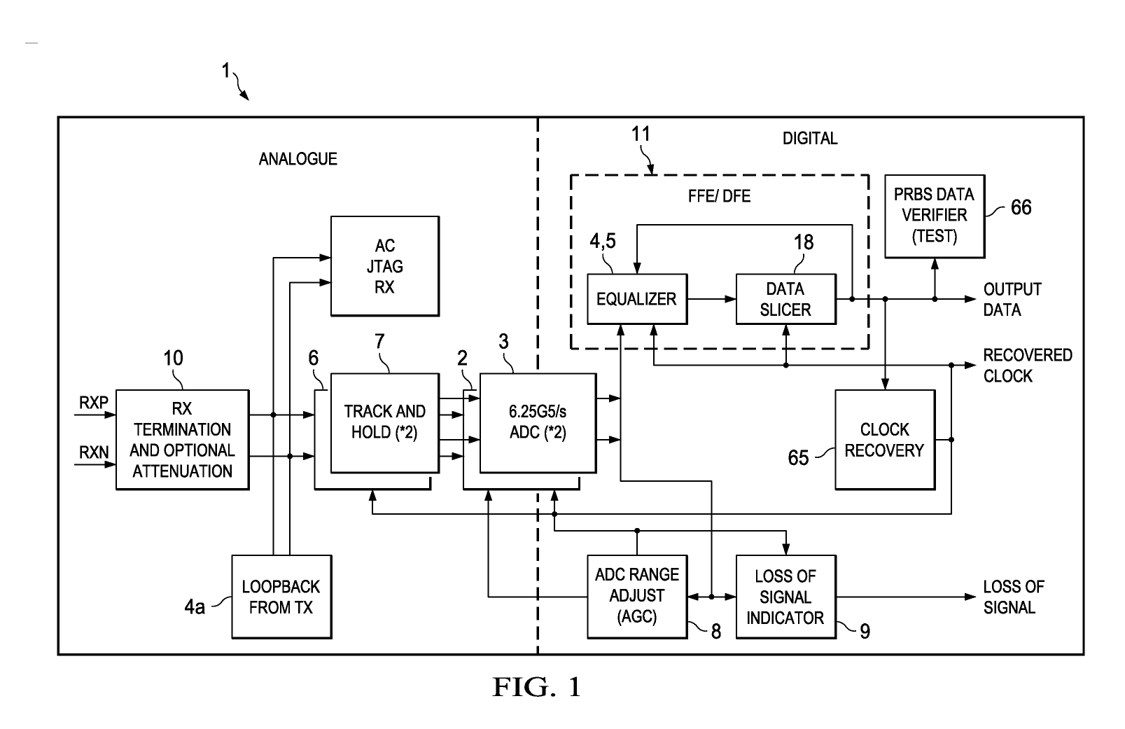

A block diagram of a SerDes receiver circuit 1, which forms part of an integrated circuit, in which the present invention may be used is shown in FIG. 1. The invention may nonetheless be used in other applications.

In the receiver circuit 1 of FIG. 1 the input data is sampled at the baud-rate, digitized and the equalization and clock & data recovery (CDR) performed using numerical digital processing techniques. This approach results in the superior power/area scaling with process of digital circuitry compared to that of analogue, simplifies production testing, allows straightforward integration of a feed-forward equalizer and provides a flexible design with a configurable number of filter taps in the decision feedback equaliser. The circuit has been implemented in 65 nm CMOS, operating at a rate of 12.5 Gb/s.

The receiver circuit 1 comprises two baud-rate sampling ADCs (analogue to digital converters) 2 and 3, a digital 2-tap FFE (feed forward equaliser) 4 and digital 5-tap DFE (decision feedback equaliser) 5 to correct channel impairments.

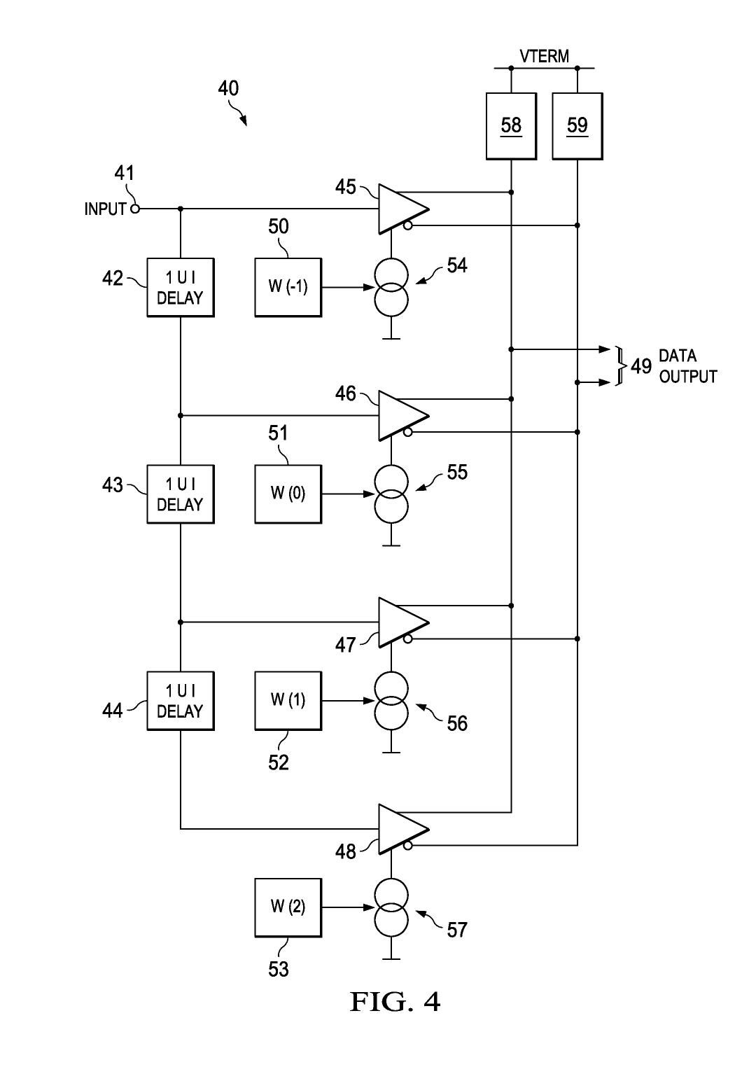

The SerDes section of the integrated circuit, which includes the receiver circuit 1 is also provided with a transmitter 40 (FIG. 4), connected to transmit data over a parallel channel to that which the receiver circuit 1 is connected to receive data. The transmitter 40 comprises a 4-tap FIR filter to pre-compensate for channel impairments. In many applications the integrated circuit transmitting data to the receiver circuit 1 uses pre-compensation and in particular a similar transmitter circuit 40, but in other applications the receiver circuit 1 works without pre-compensation being used at the other end

The receiver 1 of FIG. 1 is now described in more detail. The received data is digitized at the baud-rate, typically 1.0 to 12.5 Gb/s, using a pair of interleaved track and hold stages (T/H) 6 and 7 and a respective pair of 23 level (4.5 bit) full-flash ADCs 2 and 3 (i.e. they sample and convert alternate bits of the received analogue data waveform). The two track & hold circuits enable interleaving of the half-rate ADCs and reduce signal related aperture timing errors. The two ADCs, each running at 6.25 Gb/s for 12.5 Gb/s incoming data rate provide baud-rate quantization of the received data. The ADC's dynamic range is normalized to the full input amplitude using a 7-bit automatic gain control (AGC) circuit 8. A loss of signal indication is provided by loss of signal unit 9 that detects when the gain control signal provided by the AGC is out-of-range. An optional attenuator is included in the termination block 10, which receives the signals from the transmission channel, to enable reception of large signals whilst minimizing signal overload.

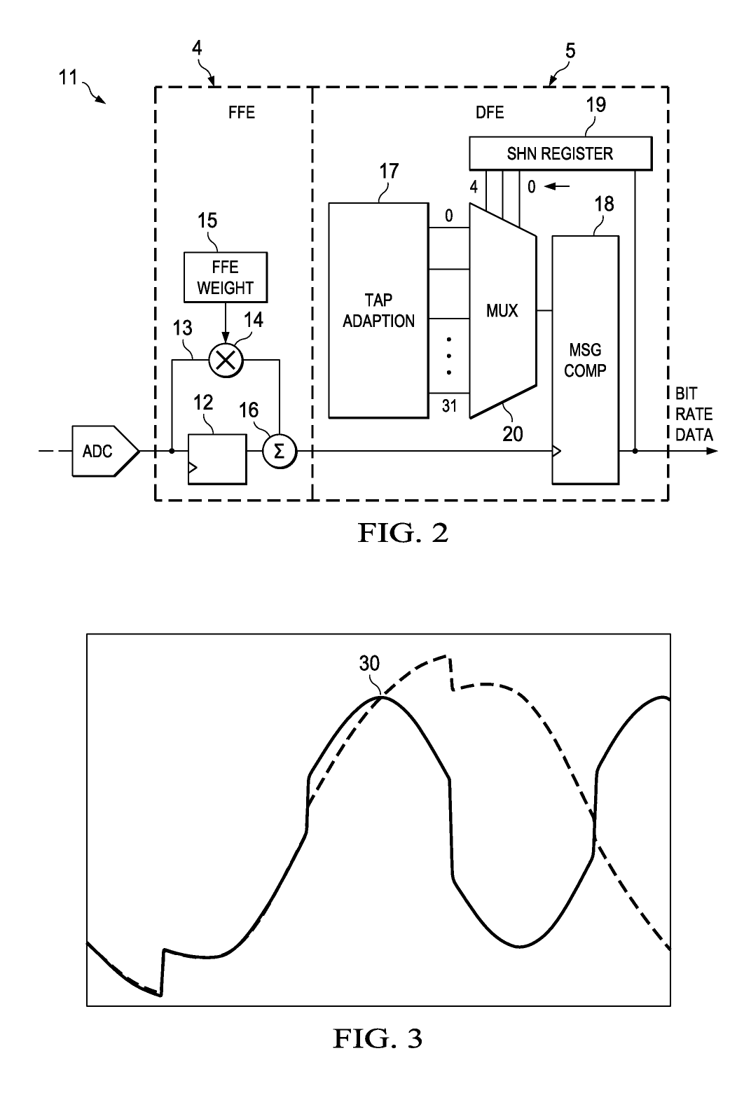

The digital samples output from the ADCs 2 and 3 are interleaved and the resulting stream of samples is fed into a custom digital signal processing (DSP) data-path that performs the numerical feed-forward equalization and decision-feedback equalization. This is shown in FIG. 2. This comprises a 1 UI delay register 12 connected to receive the stream of samples from the ADCs 2 and 3. (1 UI is a period of the clock, i.e. the delay between bits.) A tap 13 also feeds the samples from the ADCs to a multiplier 14, each sample being received by the delay latch 12 and the multiplier 14 at the same time. The multiplier 14 multiplies each sample by a constant weight value (held in a programmable register 15), which value is typically 10%. The outputs of the multiplier 14 and the delay register 12 are added together by an adder 16 to provide the output of the FFE 4.

The digital FFE/DFE is implemented using standard 65 nm library gates.

An advantage of applying the equalization digitally is that it is straightforward to include feed-forward equalization as a delay-and-add function without any noise-sensitive analogue delay elements. The FFE tap weight is selected before use to compensate for pre-cursor ISI and can be bypassed to reduce latency. Whilst many standards require pre-cursor de-emphasis at the transmitter, inclusion at the receiver allows improved bit error rate (BER) performance with existing legacy transmitters.

The DFE 5 uses an unrolled non-linear cancellation method [“Techniques for High-Speed implementation of Non-linear cancellation” S. Kasturia IEEE Journal on selected areas in Communications. June 1991]. The data output (i.e. the 1s and 0s originally transmitted) is the result of a magnitude comparison between the output of the FFE 4 and a slicer-level dynamically selected from a set stored in a set 17 of pre-programmed registers. The values are determined by a control circuit (not shown in FIG. 1) from the waveforms of test patterns sent during a setup phase of operation. The magnitude comparison is performed by a magnitude comparator 18 connected to receive the output of the FFE 4 and the selected slicer-level; it outputs a 1 if the former is higher than the latter and a 0 if it is lower or equal, thereby forming the output of the DFE 5.

The slicer-level is selected from one of 2 n possible options depending on the previous n bits of data history. The history of the bits produced by the magnitude comparator 18 is recorded by a shift register 19 which is connected to shift them in. The parallel output of the shift register is connected to the select input of a multiplexer 20 whose data inputs are connected to the outputs of respective ones of the set 17 of registers holding the possible slicer-levels.

Unrolled tap adaption is performed using a least mean square (LMS) method where the optimum slicing level is defined to be the average of the two possible symbol amplitudes (+/−1) when proceeded by identical history bits. (For symmetry the symbols on the channel for the bit values 1 and 0 are given the values +1 and −1).

Although 5-taps of DFE were chosen for this implementation, this parameter is easily scaleable and performance can be traded-off against power consumption and die area. In addition, the digital equalizer is testable using standard ATPG (automatic test pattern generation) and circular built-in-self-test approaches.

The chosen clock recovery approach uses a Muller-Mueller approach [“Timing recovery in Digital Synchronous Data Receivers” Mueller and Muller IEEE Transactions on Communications May 1976.] where the timing function adapts the T/H sample position to the point where the calculated pre-cursor inter-symbol interference (ISI) or h(−1) is zero, an example being given in FIG. 3. The two curves show the post-equalized response for 010 and 011 data sequences respectively. The intersection 30 at 3440 ps occurs when the sample of the second bit is independent of the third bit—that is, h(−1)=0. This position can be detected by comparing the post-equalized symbol amplitude with the theoretical amplitude h(0) and using the difference to update the CDR's phase-interpolator.

A block diagram of the transmitter is shown in FIG. 4, which is implemented using CML techniques. The data to be transmitted (received at terminal 41) is sequentially delayed by three 1 UI delay registers 42, 43 and 44 connected in series. They produce, via the four taps before and after each delay, a nibble-wide word containing the pre-cursor, cursor and two post-cursor components. In fact to ease timing closure the data is sent to the transmitter from the digital part of the circuit that supplies the data in blocks of 4 nibbles (16 bits in parallel), the blocks being sent at a rate of 3.125/s. Each nibble is a frame of four bits of the bitstream offset by one bit from the next so the nibbles overlap and represent the data redundantly. A multiplexer then selects one of the nibbles, switching between them at a rate of 12.5×10⁹/s, and presents that in parallel to the four taps, thereby making the bitstream appear to advance along the taps.

A 4-tap FIR output waveform is obtained from simple current summing of the time-delayed contributions. This is done with differential amplifiers 45 to 48, each having its inputs connected to a respective one of the taps and having its differential output connected to a common differential output 49. Although shown as four differential amplifiers the circuit is implemented as one differential amplifier with four inputs, which minimizes return-loss. The relative amplitude of each contribution is weighted to allow the FIR coefficients to be optimized for a given circuit (e.g. a backplane) and minimize the overall residual ISI. The weights are determined empirically either for a typical example of a particular backplane or once a backplane is populated and are stored in registers 50 to 53. The weights respectively control the controllable driving current sources 54 to 57 of the differential amplifiers 45 to 48 to scale their output current accordingly. Respective pull-up resistors 58 and 59 are connected to the two terminals of the differential output 49.

A PLL is used to generate low-jitter reference clocks for the transmitter and receiver to meet standards[“OIF-CEI-02.0—Common Electrical I/O (CEI)—Electrical and Jitter Interoperability agreements for 6 G+bps and 11 G+bps I/O”. Optical Internetworking Forum, February 2005; “IEEE Draft 802.3ap/Draft 3.0—Amendment: Electrical Ethernet Operation over Electrical Backplanes” IEEE July 2006.]. Most integrated circuits will have more than one receiver 1 and the PLL is shared between them with each receiver having a phase interpolator to set the phase to that of incoming data.

The PLL uses a ring oscillator to produce four clock-phases at a quarter of the line data-rate. The lower speed clocks allow power efficient clock distribution using CMOS logic levels, but need duty-cycle and quadrature correction at the point of use. The 3.125 GHz clocks are frequency doubled (XOR function) to provide the 6.25 GHz clock for the T/H & ADC. The transmitter uses the four separate 3.125GHzphases, but they require accurate alignment to meet jitter specifications of 0.15UI p-p R.J. and 0.15UI p-p D.J.

The system described has been fabricated using a 65 nm CMOS process and has been shown to provide error-free operation at 12.5 Gb/s over short channels (two 11 mm package traces, 30 cmlow-loss PCB and two connectors). A legacy channel with −24 dB of attenuation at 3.75 GHz supports error free operation at 7.5 Gb/s.

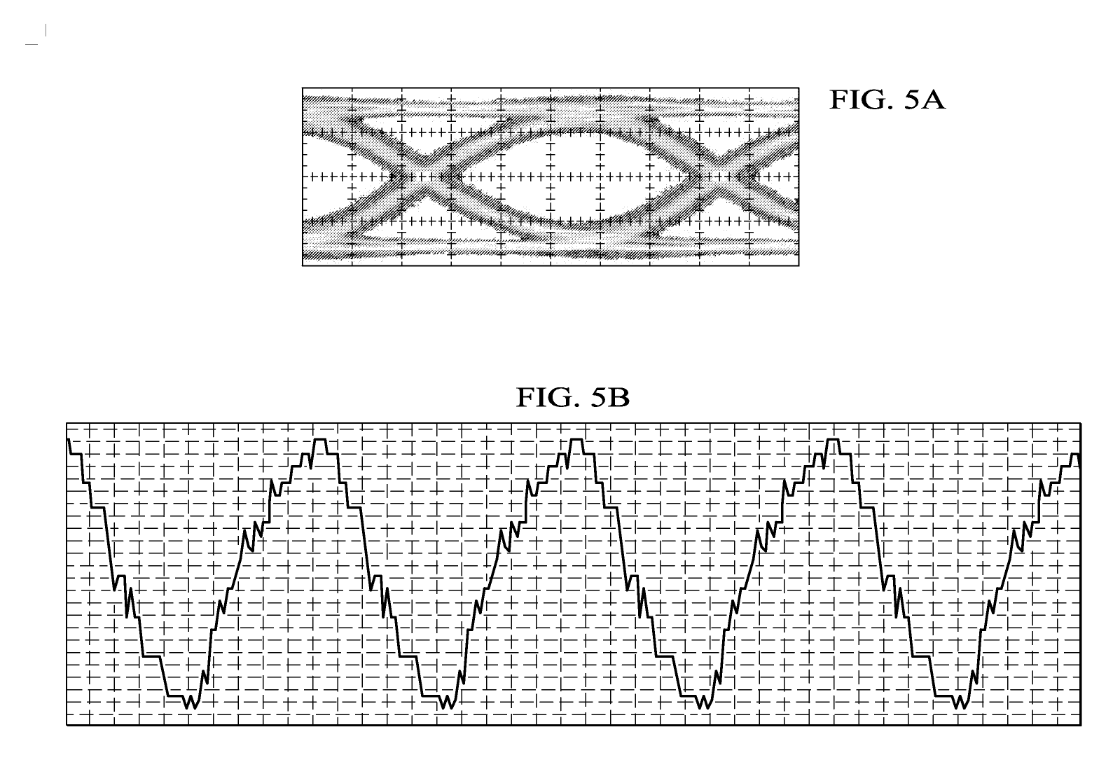

FIG. 5a shows a 12.5 Gb/s 27-1 pseudo random bit stream (PRBS) transmitted eye-pattern with 20% de-emphasis on the first post-cursor. The receiver includes, for test purposes, a PRBS data verifier 66, which confirms that the test pattern has been received. The differential peak-to-peak (pp) amplitude is 700 mV (200 mV/div). FIG. 5b shows the ADC output when a 6.25 GHz sine-wave is sampled and the phase between the sine-wave and receiver is incremented using a programmable delay-line. The measured codes are within +/−1 lsb (least significant bit) of the expected values. This level of performance ensures robust operation over a wide range of cables, green-field and legacy channels. The worst-case power of a single TX/RX pair, or “lane” is 330 mW and the total exemplary macro area is 0.45 mm² per lane (allowing for the PLL being shared by four TX/RX lanes.

FIG. 7 is a block diagram of a clock control circuit, indicated generally by the reference numeral 700, that makes use of a clock control system of the present invention. The clock control circuit 700 comprises a first CML to CMOS converter 702, a second CML to CMOS converter 704, a clock multiplier circuit 706 and a control circuit 708.

The clock control circuit 700 can be used in a SerDes for generating high frequency clock signals by multiplying lower frequency clock signals. In one exemplary embodiment of the invention, the clock control circuit 700 converts 3 GHz clock signals into 6 GHz clock signals.

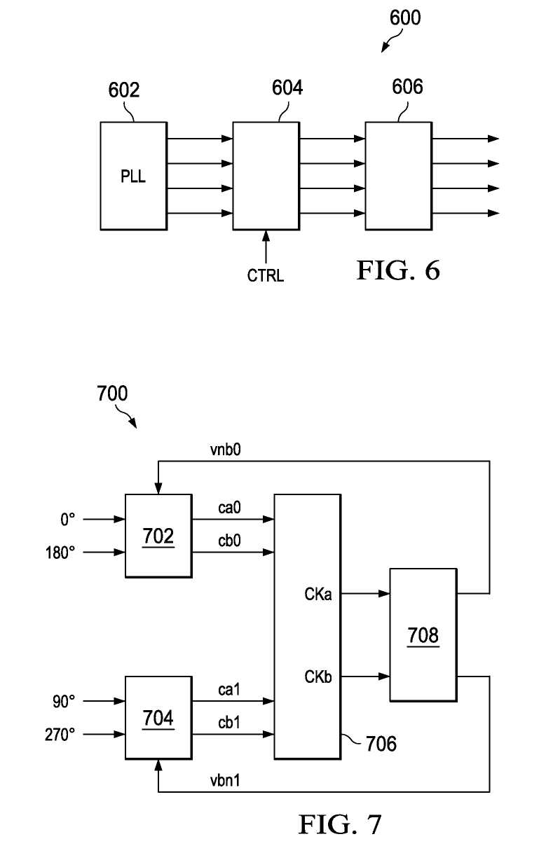

The clock control circuit 700 receives small signal clock signals that are approximately in quadrature. For example, the clock control circuit may receive the outputs of the phase adjust circuit 604 described above with reference to FIG. 6.

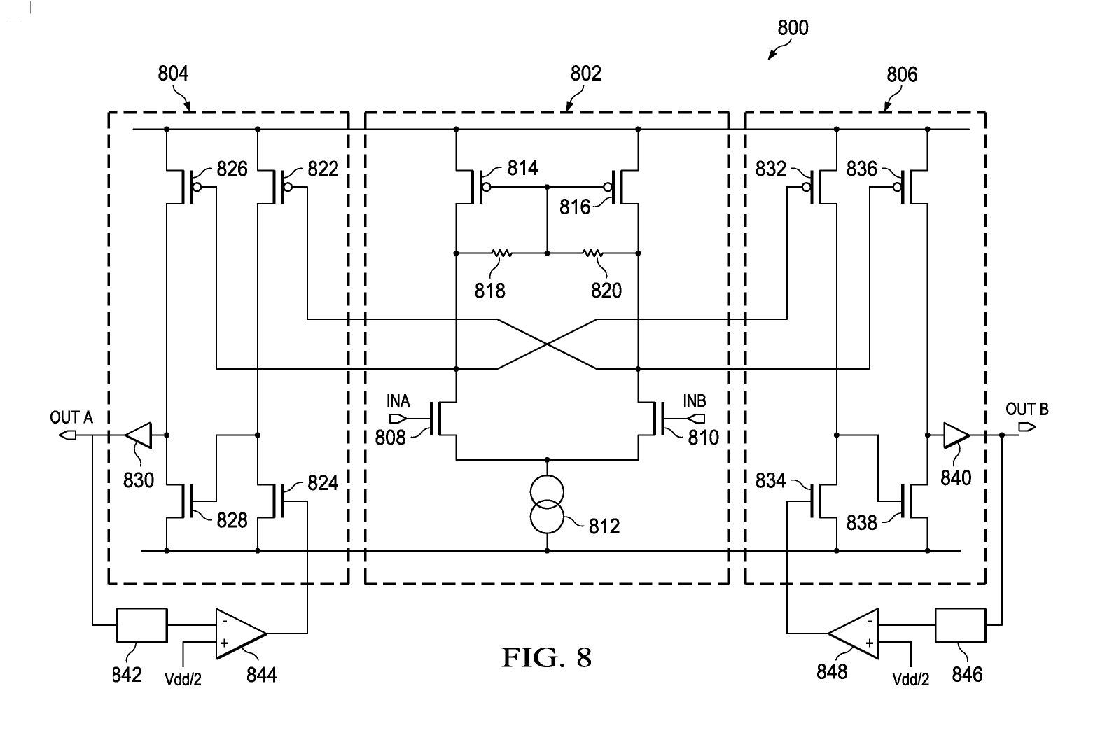

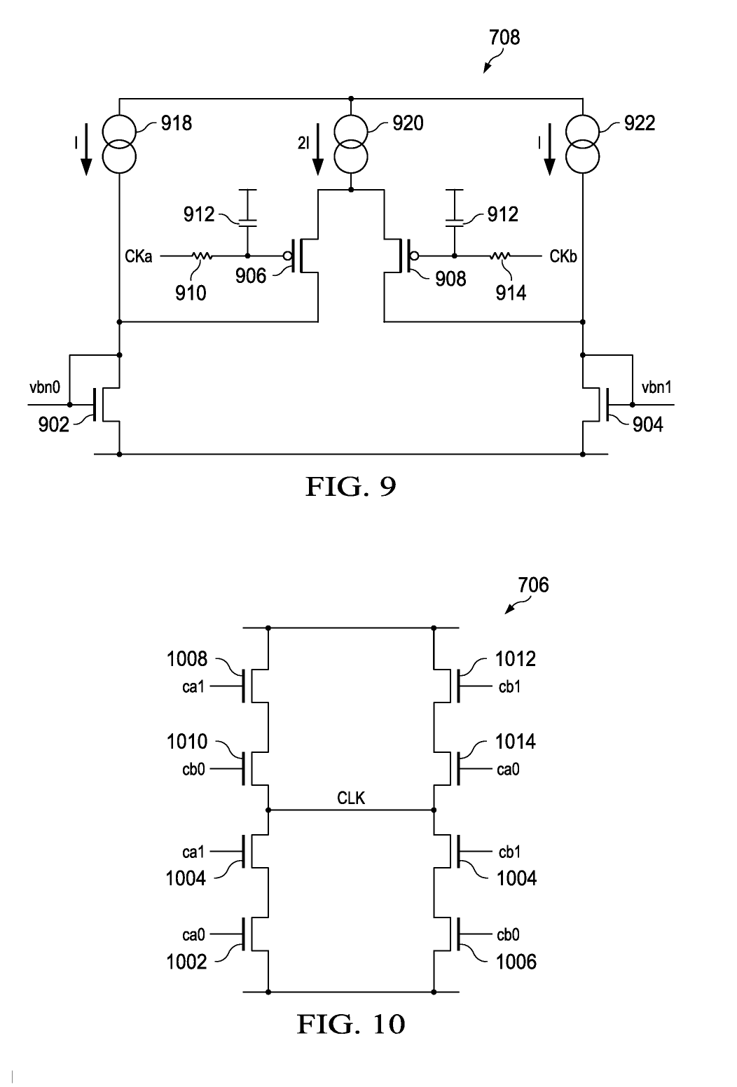

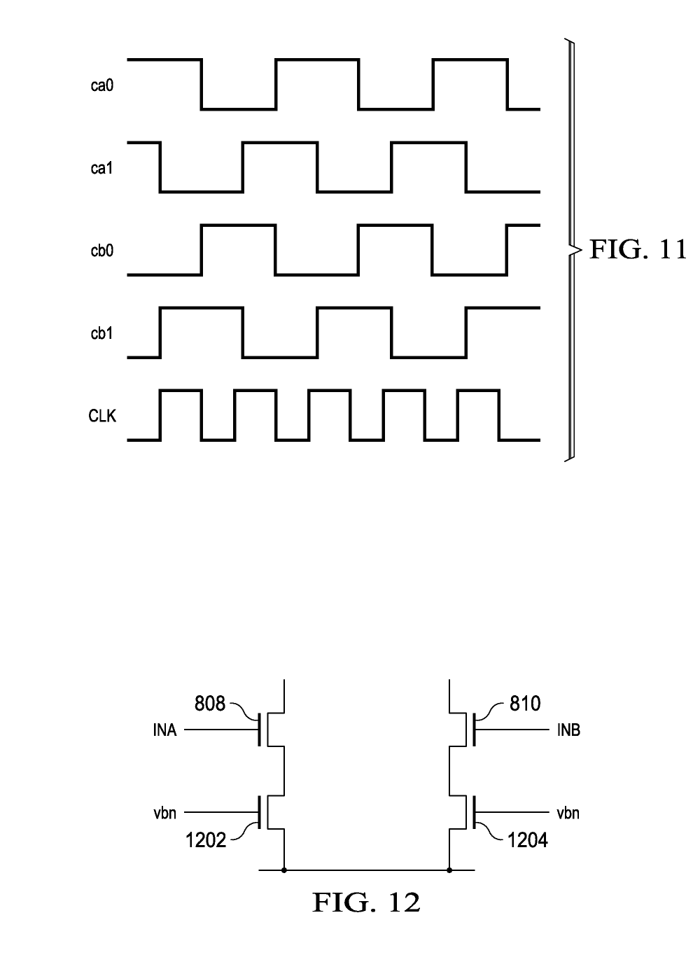

In the circuit 700, clock signals having relative phases of 0 degrees and 180 degrees are provided as the inputs to CML to CMOS converter 702 and clock signals having relative phases 90 degrees and 270 degrees are provided as the inputs to CML to CMOS converter 704. The first CML to CMOS converter provides clock signals ca0 and cb0 having relative phases of 0 degrees and 180 degrees and the second CML to CMOS converter provides clock signals ca1 and cb1 having relative phases of 90 degrees and 270 degrees in a manner described in detail below with reference to FIG. 8. The clock signals ca0, cb0, ca1 and cb1 are provided as inputs to the clock multiplier 706, which generates two complementary 6 GHz clock signals (CKa and CKb) from the four 3 GHz clock signals it receives in a manner described in detail below with reference to FIGS. 10 and 11. The control circuit 708 receives the output clock signals from said multiplier circuit 706 and provides control signals vbn0 and vbn1 for the converters 702 and 704 respectively as discussed in detail below with reference to FIG. 9.

The converters 702 and 704 convert the small-swing input clock signals into large swing clock signals and also adjust the mark-space ratio of the output clock signals, if necessary, towards 50%.

FIG. 8 is a simplified circuit schematic of a CML-CMOS converter, indicated generally by the reference numeral 800, used in an embodiment of the present invention. The converter 800 comprising a differential amplifier 802, a first push-pull stage 804, a second push-pull stage 806 and a feedback arrangement between the output and the input of each of said push-pull stages 804 and 806.

The differential amplifier comprises first 808 and second 810 NMOS transistors having gates coupled to inputs signals INA and INB respectively and sources coupled to a current source 812. The drain of first NMOS transistor 808 is coupled to the drain of first PMOS transistor 814 and to a first terminal of resistor 818. The drain of second NMOS transistor 810 is coupled to the drain of second PMOS transistor 816 and to a first terminal of resistor 820. The second terminals of resistors 818 and 820 are coupled to the gates of first and second PMOS transistors 814 and 816.

The first push-pull stage 804 comprises third 824 and fourth 828 NMOS transistors, third 822 and fourth 826 PMOS transistors and output buffer 830. The gate of third PMOS transistor 822 is coupled to the drains of second NMOS transistor 810 and second PMOS transistor 816. The drain of third PMOS transistor 822 is coupled to the drain of third NMOS transistor 824 and to the gate of fourth NMOS transistor 828. The gate of fourth PMOS transistor 826 is coupled to the drains of first NMOS transistor 808 and first PMOS transistor 814. The drains of fourth NMOS transistor 828 and fourth PMOS transistor 826 are coupled to the input of buffer 830.

The second push-pull stage 806 comprises fifth 834 and sixth 838 NMOS transistors, fifth 832 and sixth 836 PMOS transistors and output buffer 840. The gate of fifth PMOS transistor 832 is coupled to the drains of first NMOS transistor 808 and first PMOS transistor 814. The drain of fifth PMOS transistor 832 is coupled to the drain of fifth NMOS transistor 834 and to the gate of sixth NMOS transistor 838. The gate of sixth PMOS transistor 836 is coupled to the drains of second NMOS transistor 810 and second PMOS transistor 816. The drains of sixth NMOS transistor 838 and sixth PMOS transistor 836 are coupled to the input of buffer 840.

The source of each of said PMOS transistors is coupled to a positive power rail (Vdd) . The source of each of said third 824, fourth 828, fifth 834 and sixth 838 NMOS transistors are coupled to a negative power rail (typically ground).

The output of buffer 830 is connected to the negative input of comparator 844 via a first low pass filter 842. Similarly, the output of buffer 840 is coupled to the negative input of comparator 848 via a second low pass filter 848. The positive inputs of comparators 844 and 848 are held at a voltage half way between the power rail and ground (Vdd/2). The output of comparator 844 is coupled to the gate of third NMOS transistor 844. The output of comparator 848 is coupled to the gate of fifth NMOS transistor 848.

The inputs INA and INB are complementary small swing clock signals. The differential amplifier 802 and push-pull stages 804 and 806 convert this small swing clock signal into large swing clock signals OUTA and OUTB that are the outputs of the first 830 and second 840 buffer circuits respectively. The outputs OUTA and OUTB are complementary clock signals and should have a mark-space ratio of 50%.

The mean voltage level of the clock signal at the input of buffer 830 can be controlled by controlling the voltage at the gate of the third NMOS transistor 824, thereby controlling the current drive capabilities of the NMOS transistors 824 and 828. Similarly, the mean voltage level of the clock signal at the input of buffer 840 can be controlled by controlling the voltage at the gate of the fifth NMOS transistor 834. The gates of the third 824 and fifth 834 NMOS transistors are coupled to the outputs of comparators 844 and 848 respectively. Accordingly, those comparators can be used to control the slew rates of the clock signals OUTA and OUTB.

In the event that the mark-space ratio of the output OUTA is above 50%, i.e. the output OUTA is high more often than it is low, the output of the first low pass filter will be higher than Vdd/2 and so the output of the comparator will fall. If the output of the comparator 824 falls, the third NMOS transistor will have a lower current drive. As a result, the gate voltage of the fourth NMOS transistor 828 will rise under the influence of the third PMOS transistor 822. Thus, the fourth NMOS transistor 828 has a higher drive capability, which results in a reduction in the rate at which the output OUTA is pulled from a logic 1 to a logic 0, thereby resulting in an output that is high for longer. Thus, the circuit moves towards a mark-space ratio of 50%.

Similarly, in the event that the mark-space ratio of the output OUTA is below 50%, i.e. the output OUTA be high less often that it is low, the output of the first low pass filter will be low than Vdd/2 and so the output of the comparator will rise. If the output of the comparator 824 rises, the third NMOS transistor 824 will have a greater current drive capability. As a result, the gate voltage of the fourth NMOS transistor 828 will fall. Thus, the fourth NMOS transistor has a lower drive capability, which results in an increase in the rate at which the output OUTA is pulled from a logic 1 to a logic 0, thereby resulting in an output that is lower for longer. Thus, the circuit moves towards a mark-space ratio of 50%.

The feedback arrangement therefore results in an output OUTA that tends towards a mark-space ratio of 50%. In a similar manner, the output OUTB tends towards a mark-space ratio of 50% under the control of the comparator 848. The output clock signals could be made to have a mark-space ration different to 50%, for example by changing the voltage at the positive inputs to the comparators 844 and 848.

As described above with reference to FIG. 7, the CML-CMOS converter circuit 702 receives clock signals having relative phases of approximately 0 degrees and 180 degrees. As described above with reference to FIG. 8, the converter circuit 702 reduces any errors in the relative phases of those clock signals so that the outputs of the circuit 702 are closer to being ideal complementary clock signals than the clock signals at the input. The output OUTA of the CMOS converter circuit 702 provides the clock signal ca0: the output OUT B of the CML-CMOS converter circuit 702 provides the clock signal cb0.

In a similar manner, the CML-CMOS converter circuit 704 receives clock signals having relative phases of approximately 90 degrees and 270 degrees. Again, any error in the relative phases of these clock signals is reduced by the circuit 704 such that the outputs of the circuit 704 are closer to being ideal complementary clock signals than the signals at the input. The output OUTA of the CMOS converter circuit 704 provides the clock signal ca1: the output OUT B of the CML-CMOS converter circuit 704 provides the clock signal cb1.

It should be noted, however, that although CML-CMOS converter circuits 702 and 704 as described above correct for errors in the relative phases of the input signals of those circuits, there is no correction of any errors between the phases at the output of circuit 702 and the phases at the output of circuit 704. For example, if the relative phases at the output of circuit 702 are 0 degrees and 90 degrees and the relative phases at the output of circuit 704 are 92 degrees and 272 degrees, the circuits as described above with reference to FIG. 8 will not make any adjustments, even though those signals are not in quadrature. Correcting for such errors is the purpose of the control signals output by the control circuit 708.

FIG. 9 is a simplified circuit schematic of the control circuit 708. The control circuit 708 comprises seventh 902 and eighth 904 NMOS transistors, seventh 906 and eighth 908 PMOS transistors, resistors 910 and 914, capacitors 912 and 916 and current sources 918, 920 and 922.

The control circuit 708 receives the complementary clock signals CKa and CKb that are output by the clock multiplier 706. If the inputs to the clock multiplier 706 are in perfect quadrature, then the clock signals CKa and CKb should be complementary, with each having a mark-space ratio of 50%. If the inputs to the clock multiplier are not in perfect quadrature, then the outputs of the clock multiplier will not be ideal complementary clock signals having a mark-space ratio of 50%. This non-ideality is detected by the control circuit 708 and used to generate control signals vbn0 and vbn1 which are fed back to the converter circuits 702 and 704 and used to adjust the clock outputs of the circuits 702 and 704, as described below.

The clock input CKa to the control circuit 708 is coupled to a first terminal of resistor 910, the second terminal of which is coupled to a first terminal of capacitor 912 and to the gate of seventh PMOS transistor 906. Similarly, the clock input CKb to the control circuit 900 is coupled to a first terminal of resistor 914, the second terminal of which is coupled to a first terminal of capacitor 916 and to the gate of eighth PMOS transistor 908. The sources of seventh 906 and eighth 908 PMOS transistors are coupled to current source 920, which current source provides a constant current 2I.

The drain of seventh PMOS transistor 906 is coupled to the gate and the drain of seventh NMOS transistor 902 and to the current source 918, which current source provides a constant current I. Similarly, the drain of eighth PMOS transistor 908 is coupled to the gate and the drain of eighth NMOS transistor 904 and to the current source 922, which current source provides a constant current I.

The gate of said seventh NMOS transistor 902 provides the control signal vbn0. The gate of said eighth NMOS transistor 904 provides the control signal vbn1.

The circuit 700 functions as follows.

If the clock signal CKa is high for a longer period of time than the clock signal CKb, then the voltage at the gate of the seventh PMOS transistor 906 will be higher than the voltage at the gate of the eighth PMOS transistor 908. Thus, the eighth PMOS transistor 908 will be more strongly on than the seventh PMOS transistor 906 and a higher proportion of the current from current source 920 will be routed to the transistor 904 than the transistor 902. Thus, the current passing through transistor 904 will be higher than the current passing through the transistor 902 and so the signal vbn1 will have a higher voltage than the control signal vbn0.

Conversely, if the clock signal CKb is high for a longer period of time than the clock signal CKa, then the voltage at the gate of the seventh PMOS transistor 906 will be lower than the voltage at the gate of the eighth PMOS transistor 908. Thus, the seventh PMOS transistor 908 will be more strongly on than the eighth PMOS transistor 906 and a higher proportion of the current from current source 920 will be routed to the transistor 902 than the transistor 904. Thus, the current passing through transistor 902 will be higher than the current passing through the transistor 904 and so the signal vbn0 will have a higher voltage than the control signal vbn1.

In this way, the control signals vbn0 and vbn1 provide a measure of how closely the clock inputs CKa and CKb resemble the desired complementary clock signals. The control signal vbn0 and vbn1 are used as control inputs to the CML-CMOS converters 702 and 704 respectively.

FIG. 10 is a clock multiplier circuit that could be used as the clock multiplier 706 of the present invention. The clock multiplier 706 comprises first 1000, second 1002, third 1004 and fourth 1006 NMOS transistors and first 1008, second 1010, third 1012 and fourth 1014 PMOS transistors.

The first NMOS transistor 1002 has a gate coupled to the input ca0, a drain coupled to the source of the second NMOS transistor 1004 and a source coupled to ground. The second NMOS transistor 1004 has a gate coupled to the input ca1, and a drain coupled to the output CLK. The third NMOS transistor 1004 has a gate coupled to the input cb1, a drain coupled to the output CLK and a source coupled to the drain of the fourth NMOS transistor 1006. The fourth NMOS transistor 1006 has a gate coupled to the input cb0 and a source coupled to ground. The first PMOS transistor 1008 has a gate coupled to the input ca1, a source coupled to the power rail Vdd and a drain coupled to the source of second PMOS transistor 1010. The second PMOS transistor 1010 has a gate coupled to the input cb0 and a drain coupled to the output CLK. The third PMOS transistor 1012 has a gate coupled to the input cb1, a source coupled to the power rail Vdd and a drain coupled to the source of fourth PMOS transistor 1014. The fourth PMOS transistor has a gate coupled to the input ca0 and a drain coupled to the output CLK.

The clock multiplier circuit 706 functions as follows.

When the inputs ca1 and cb0 are both low, the first 1008 and second 1010 PMOS transistor are turned on and the output CLK is pulled high. Similarly, when the inputs cb1 and ca0 are both low, the third 1012 and fourth 1014 PMOS transistor are turned on and the output CLK is pulled high. When the inputs ca1 and ca0 are both high, the first 1002 and second 1004 NMOS transistors are turned on and the output CLK is pulled low. Similarly, when the inputs cb1 and cb0 are both high, the third 1004 and fourth 1006 NMOS transistors are turned on and the output CLK is pulled low.

The inputs ca0, ca1, ca1 and cb1 are the four clock outputs of the CML-CMOS converters 702 and 704. Those four clock inputs are in quadrature. If the input signal ca0 has a phase 0 degrees, then the inputs ca1, cb0 and cb1 have the phases 90 degrees, 180 degrees and 270 degrees respectively. Thus, the inputs ca0 and cb0 should be complementary and the inputs ca1 and cb1 should be complementary.

FIG. 11 is a timing diagram demonstrating the functionality of the clock multiplier circuit 706. The timing diagram shows the four clock signals ca0, ca1, cb0 and cb1 having the relative phases described above.

At the start of FIG. 11, the inputs ca0, ca1, cb0 and cb1 have the values 1, 1, 0 and 0 respectively. Thus, the first 1002 and second 1004 NMOS transistors are on and the output CLK is pulled low. Next, the complementary signals ca1 and cb1 change state, with the signals ca1 and cb0 remaining unchanged. At this time, the first 1008 and second 1010 PMOS transistors are both turned on and the output CLK is pulled high. Next, the states of the inputs ca0 and cb0 changes and the third 1004 and fourth 1006 NMOS transistors are turned on such that the output CLK is pulled low. Next, the states of the inputs ca1 and cb1 change and the third 1012 and fourth 1014 PMOS transistors are turned on and the output CLK is pulled high. This cycle of clock transitions is then repeated.

As can be seen in FIG. 11, the output CLK has a frequency twice that of each of the inputs ca0, ca1, cb0 and cb1. It is also apparent from the discussion above that small errors in the relative phases of the input signals will result in unclean data transitions of the clock output CLK. Thus, as discussed above, it is important that the clock signals ca0, ca1, cb0 and cb1 are in quadrature.

In one implementation of the invention, the clock multiplier circuit 706 is used in conjunction with a similar circuit but one having different inputs. In this second circuit, the inputs to the first and second NMOS transistors are reversed, the inputs to the first and second PMOS transistors are reversed, the inputs to the third and fourth NMOS transistors are reversed and the inputs to the third and fourth PMOS transistors are reversed. This additional circuit has the same logical functionality as that of the circuit 706; however, the inclusion of the second circuit improves the symmetry of the overall clock multiplier circuit thereby increasing the matching of the rise and fall times of the output clock signal. Further, the output CLK may be buffered and an inverter may be provided in order to provide a complementary clock output CLKZ.

As described above with reference to FIGS. 7 and 8, the CML-CMOS converter circuits 702 and 704 include a current source 812. The current source 812 is implemented as shown in FIG. 12. FIG. 12 shows the NMOS transistors 808 and 810 as shown in FIG. 8. In addition, the current source 812 includes NMOS transistors 1202 and 1204. The NMOS transistor 1202 has a gate coupled to the control signal vbn, a drain coupled to the source of NMOS transistor 808 and a source coupled to ground. The NMOS transistor 1204 has a gate coupled to the control signal vbn, a drain coupled to the source of NMOS transistor 810 and a source coupled to ground.

The current source 812 is controlled by the control signal vbn such that the higher that control signal, the higher the current that passes through the current source. This is used to control the CML-CMOS converters 702 and 704.

The control signals vbn work as follows.

If vbn rises, the current source 812 has an increased current drive capability. As a result, the push-pull stages 804 and 806 have a higher drive capability and therefore faster switching times. This results in reduced delays through the CML-CMOS converter 800, which results in the output clock signals appearing earlier, thereby adjusting the phase of those clock signals. Conversely, if vbn falls, the current source 812 has a lower drive capability leading to a reduction in switching times throughout the CML-CMOS converter 800 and a corresponding adjustment of the phase of the output clock signals.

The implementation of the clock control system of the present invention has been described above as part of a receiver circuit. The clock control system could be used in other applications. Indeed, the circuit 700 described above with reference to FIG. 7 could be used as part of a transmitter circuit.

In the receiver arrangement described above, it is assumed that the described clock signals are the signals CKa and CKB output by the clock multiplier circuit 706. In a transmitter arrangement, the desired clock signals may well be the four quadrature clock signals Ca0, Cb0, Ca1, Cb1. The circuit of FIG. 7 can still be used in such an arrangement by merely taking the clock signals Ca0, Cb0, Ca1, Cb1 as the outputs rather than the clock signals CKa and CKb. Thus, in such a transmitter arrangement, the clock multiplier circuit 706 forms part of a control circuit, but the double rate clock outputs are not themselves provided as an output.

1. A clock correction circuit comprising:
a differential amplifier comprising first and second inputs and first and second outputs, wherein, in use, said first and second inputs receive first and second small signal clock signals respectively;
a first push-pull output stage comprising an input and an output, wherein said input is coupled to the first output of said differential output and said output provides a first clock output signal;
a second push-pull output stage comprising an input and an output, wherein said input is coupled to the second output of said differential output and said output provides a second clock output signal;
a first feedback loop circuit comprising an input and an output, wherein the input is coupled to the output of said first push-pull output stage and wherein said first feedback loop circuit is adapted to provide a first control signal at said output that is indicative of the difference between the mean level of said first clock output signal and a desired mean level of said first clock output signal, wherein the output of said first feedback loop is coupled to a control input of said first push-pull output stage; and
a second feedback loop circuit comprising an input and an output, wherein the input is coupled to the output of said second push-pull output stage and wherein said second feedback loop circuit is adapted to provide a second control signal at said output that is indicative of the difference between the mean level of said second clock output signal and a desired mean level of said second clock output signal, wherein the output of said second feedback loop is coupled to a control input of said second push-pull output stage,
wherein the current drive of an input stage of said first push-pull output stage is dependent on the output of said first feedback loop circuit and the current drive of an input stage of said second push-pull output stage is dependent on the output of said second feedback loop circuit, such that, in use, the mean level of the signals at said first and second outputs of said clock correction circuit are adjusted towards the said desired mean levels.

2. A clock correction circuit as claimed in claim 1, wherein said desired mean levels of said signals at said first and second outputs of said clock correction circuit are 50% of the supply voltage.

3. A clock correction circuit as claimed in claim 1, wherein said first and second output clock signals are complementary clock signals.

4. A clock correction circuit as claimed in claim 1, wherein said first feedback loop circuit comprises a first low pass filter and a first comparator and said second feedback loop circuit comprises a second low pass filter and a second comparator.

5. A clock correction circuit as claimed in claim 4, wherein:
said first low pass filter has an input coupled to the output of said first push-pull output stage and an output coupled to a first input of said first comparator;
said first comparator has an output providing said first control signal;
said second low pass filter has an input coupled to the output of said second push-pull output stage and an output coupled to a first input of said second comparator; and
said second comparator has an output providing said second control signal.

6. A clock correction circuit as claimed in claim 4, wherein said first comparator has a second input connected to a voltage equivalent to said desired mean level of said first output clock signal and said second comparator has a second input connected to a voltage equivalent to said desired mean level of said second output clock signal.

7. A clock correction circuit as claimed in claim 1, wherein said differential amplifier further comprises a variable current source controlled in dependence on a control input.

8. A clock control circuit comprising:
a first clock correction circuit having first and second inputs for receiving first and second small signal clock signals and first and second outputs for providing first and second large signal clock signals, said first clock correction circuit comprising a first differential amplifier having a variable current source controlled in dependence on a control input;
a second clock correction circuit having first and second inputs for receiving third and fourth small signal clock signals and first and second outputs for providing third and fourth large signal clock signals, said second clock correction circuit comprising a second differential amplifier having a variable current source controlled in dependence on a control input;
a clock multiplier having first and second inputs coupled to said first and second outputs of said first clock correction circuit and third and fourth inputs coupled to said first and second outputs of said second clock correction circuit, wherein, when the signals at the first and second inputs of said clock multiplier are complementary and the signals at the third and fourth inputs of said clock multiplier are complementary, the output of the clock multiplier is given by both the exclusive OR of the first and third inputs and the exclusive OR of the second and fourth input; and
a control circuit comprising first and second inputs coupled to the first and second outputs of said clock multiplier respectively and first and second outputs coupled to the control inputs of said first and second clock correction circuit respectively, wherein:
when the signal at the first output of said clock multiplier is high for a longer period of time that the signal at said second output of said clock multiplier, the first output of said control circuit has a higher voltage than the second output of said control circuit; and
when the signal at the second output of said clock multiplier is high for a longer period of time that the signal at said first output of said clock multiplier, the second output of said control circuit has a higher voltage than the first output of said control circuit,
whereby the current drive of the first differential amplifier is dependent on the first output of said control circuit and the current drive of the second differential amplifier is dependent on the second output of said control circuit, such that, is use, said first, second, third and fourth large signal clock signals are adjusted towards quadrature.

9. A clock control circuit as claimed in claim 8, wherein:
a first output of said clock multiplier is pulled high if said first and fourth inputs of said clock multiplier are both low or said second and third inputs of said clock multiplier are both low; and
the first output of said clock multiplier is pulled low if said first and third inputs of said clock multiplier are both high or said second and fourth inputs of said clock multiplier are both high.

10. A method of reducing error in the relative phase of quadrature clock signals which are required to have as close to that precise phase relationship as possible including the step of bringing signals which should be 180 degrees apart closer to a 50% duty cycle.
